(19) United States
(12) Patent Application Publication
(10) Pub. No.: US 2006/0197118 A1
(43) Pub. Date: Sep. 7, 2006

(54) Detection of molecular interactions using a field effect transistor

(76) Inventors: Piero Migliorato, Cambridge (GB); Pedro Miguel De Lemos Correia Estrela, Cambridge (GB); Feng Yan, Cambridge (GB)

Correspondence Address: BEYER WEAVER & THOMAS, LLP, P.O. BOX 70250, OAKLAND, CA, 94612-0250, US

(21) Appl. No.: 11/377,853

(22) Filed: Mar. 16, 2006

Related U.S. Application Data
(63) Continuation of application No. PCT/GB04/04005, filed on Sep. 17, 2004.

(30) Foreign Application Priority Data
Sep. 19, 2003 (GB) 0322010.0

(51) Int. Cl. H01L 23/58; H01L 21/00

(52) U.S. Cl. 257/253; 438/49

(57) ABSTRACT

A sensor for use in the detection of a molecular interaction comprises a field effect transistor (FET) having a core structure and an extended gate structure, the core structure and the extended gate structure being located on substantially separate regions of a substrate, the extended gate structure including an exposed metal sensor electrode on which probe molecules can be immobilized, wherein, in use, the sensor is operative to produce a change in an electrical characteristic of the FET in response to molecular interaction at the exposed surface of the metal sensor electrode. The sensor is particularly suitable for detecting biomolecular interactions such as the hybridization of DNA, when the sensor is prepared with suitable probe molecules immobilized on the exposed gate metal.

### CROSS-REFERENCE TO RELATED APPLICATION

This application is a continuation of co-pending International Application No. PCT/GB 04/04005, filed Sep. 17, 2004, which designated the United States and was published in English.

### FIELD OF THE INVENTION

The present invention relates to the detection of molecular interactions, particularly the hybridization of DNA, by means of a field effect transistor with a functionalized metal gate.

### BACKGROUND OF THE INVENTION

The detection of molecular interactions is important for analyzing the chemistry or biochemistry of such interactions and may also be used for identifying certain species participating in the interactions. A range of interactions may be detected when a first type of molecules (probe molecules), that are attached to a metal, are exposed to other molecules (target molecules). A good example of this type of interaction is where DNA probe oligomers with A bases attach to DNA target oligomers with T bases. The ability to detect such a reaction is essential in the field of genomics. One commonly employed method in monitoring the interaction is optical detection. Here, known DNA strands are immobilised at selected locations and the target is labelled with fluorophors. Evidence of the hybridization of a target with a complementary probe is evinced from the presence of fluorescence at the location of the probe. However, the method is expensive and difficult to implement in portable instrumentation.

An alternative approach, which aims to overcome these drawbacks, uses the field effect transistor (FET) for label-free, electrical detection. DNA hybridisation has been detected by this technique. In one reported device a structure was employed that did not have a metal gate, the voltage being applied via an electrolyte. In this example, the probes were immobilised onto silicon or silicon based insulators, such as silicon dioxide and silicon nitride. The presence of chemical or biological molecules immobilized on the gate results in a change of the interfacial dipole affecting the potential drop across the electrochemical double layer. This modulates the voltage applied to the gate of the devices, resulting in a change of the characteristics of the FET. However, when an electrolyte is placed directly in contact with silicon based insulators or other commonly used gate dielectric materials such as metal oxides or semiconductor oxides, problems such as adsorption of hydrogen or other ions, hydration or even superficial migration of ions occur at the surface of the gate dielectric. Depending on the material used, these processes often render the device unstable for operation in a liquid environment or dependent on the concentration of hydrogen (pH dependence) or other ions present in the electrolyte.

The immobilization of biomolecules on silicon-based substrates requires that several (bio)chemical processes or reactions be performed on the surface. An example is silanization of the substrate and subsequent immobilisation of an intermediate molecule, prior to the immobilisation of the chemically modified biomolecule. As a consequence of applying multiple processes, the surfaces so produced are often irreproducible, and it is difficult to control the formation of monolayers of biological molecules. Furthermore, semiconductors and insulator surfaces, such as silicon, silicon oxide, and silicon nitride are subject to uncontrolled modifications and contaminations, which add to the problem of achieving reproducible assays.

In contrast, the formation of self-assembled monolayers onto gold (Au) substrates via thiolated CH₂ chains is a well-known chemistry and can be achieved with a single biochemical step. Biomolecules modified with a thiol group can easily be assembled onto Au substrates, simply by placing a solution containing the modified biomolecules in contact with the gold substrate for a certain period of time. The time required to form a monolayer, and the concentration of probe molecules, can be controlled by applying a voltage between the Au substrate and the solution. The result of the process is the reproducible formation of monolayers of biomolecules. Furthermore, metals such as gold (Au) or platinum (Pt) are immune to oxidation and their surface can be rendered clean and reproducible by a variety of techniques, including chemical etching, chemical or plasma cleaning and thermal annealing.

The use of a thin film transistor (TFT) with Au metal gate, on which a probe can be immobilized in the manner described above, has been proposed as a DNA sensor. The device comprises a conventional polycrystalline silicon thin film transistor (PTFT) with an Au layer fabricated on top of the TFT channel area. Thus the device combines the advantages of an electrical detector, having internal amplification, with the known chemistry/biochemistry of molecular immobilization on gold substrates. However, this device configuration has a number of drawbacks and cannot be applied to the bottom gate TFT. Perhaps the most important design failing is the disadvantage of having the functionalized metal sensing area, where voltage modulation occurs, in close proximity to the field effect transistor, where amplification occurs. This leads to difficulty in isolating the device, both chemically and electrically, particularly when in contact with an electrolyte. Although a passivation layer may be applied to the device, the layer must leave some, or all, of the Au electrode region of the FET gate exposed. As a consequence, both electric current and chemical leakage may occur at the interface, penetrating into the FET structure and causing device failure.

### SUMMARY OF THE INVENTION

According to one aspect of the present invention, there is provided a sensor for use in the detection of a molecular interaction comprising a field effect transistor (FET) having a core structure and an extended gate structure, the core structure and the extended gate structure being located on substantially separate regions of a substrate, the extended gate structure including an exposed metal sensor electrode on which probe molecules can be immobilized, wherein, in use, the sensor is operative to produce a change in an electrical characteristic of the FET in response to molecular interaction at the exposed surface of the metal sensor electrode.

By spatially separating the FET gate structure, including exposed metal sensor electrode, from the remaining core FET structure, including the source and drain, the core structure is inherently isolated from the sensing region.

Preferably, the FET comprises a metal insulator semiconductor (MIS) type structure. The MIS type FET has known advantages over other types of FET. Such advantages can include high DC impedance, large gate voltage swings, high source-drain breakdown voltage and reduced gate leakage.

The extended gate geometry of the device permits passivation of the core FET structure independently of the gate structure and also allows provision of a separate electrical connection to the sensing electrode, without compromising the isolation of the rest of the FET structure.

Preferably, the sensor further comprises a passivation layer located above the core FET structure. Preferably, the passivation layer is formed from polyimide, although other materials such as BCB and Si₃N₄ are possible, as are multiple layers of different materials such as SiO₂ and Si₃N₄.

Preferably, the sensor further comprises means for electrical connection to the sensor electrode.

Preferably, the sensor electrode is substantially formed from gold. Alternatively, the sensor electrode may be substantially formed from chromium or platinum.

In the present invention a metal layer is used to passivate the underlying gate material, allowing its use in a range of aqueous environments. In contrast to prior art devices, the gate semiconductor or insulating material is protected from hydration or other ionic diffusion processes by the metal, thereby maintaining its dielectric properties. Metals such as gold are inert to most electrolytes of interest and their conductive properties are not affected by the ionic content of an electrolyte. The FET characteristics are therefore well defined, stable in an aqueous environment and independent of the ionic strength and pH of an electrolyte in contact with the exposed gate metal.

It is preferred that the sensor further comprises a reference electrode. Preferably, means are provided for applying a voltage difference between a part of the FET and the reference electrode. In particular, a voltage difference may be applied between the reference electrode and sensor electrode, in order to influence molecular immobilization or interaction time.

In prior art devices, no separate electrical connection is provided to the Au electrode and, indeed, the designs employed make this difficult. Provision of a connection enables the application of a voltage difference between a reference electrode and the Au sensor electrode. In the absence of such an applied voltage, many of the necessary chemical/biochemical processes can take a long time. This includes not only the processes required in the preparation and fabrication of the device, such as immobilization of probe molecules, but also the molecular interaction of interest, such as the hybridization of a complementary target. Without the facility for independent electrical control, the system is unsuitable for mass production and high throughput screening.

A range of both chemical and biochemical interactions may be detected with the sensor, depending on the nature of the probe molecules subsequently immobilized on the metal sensor.

Preferably, the sensor further comprises at least one probe molecule immobilized on the exposed metal sensor electrode.

Preferably, the probe molecule is selected from a group which includes proteins, antibodies and antigens, vitamins, peptides, sugars and oligonucleotides, including DNA, RNA and PNA.

Preferably, the sensor further comprises an electrolyte in contact with the probe molecules. The electrolyte can serve as a suitable host for target molecules and also complete an electrical circuit between the sensor electrode and the reference electrode.

In addition to an individual sensor, there is provided a sensor array comprising a plurality of sensors, each sensor being in accordance with the one aspect of the present invention. The sensor array may be a 1-dimensional (linear) array or a 2-dimensional array. The array may be provided with additional circuitry for control or data capture, giving additional functionality in monitoring the interaction.

Preferably, the sensor array further comprises scan and sensor circuitry connected to the sensor electrodes of at least two sensors in the array.

Preferably, the sensor array further comprises means for a switchable connection to the sensor electrode of at least one sensor in the array.

In addition to characterizing a particular interaction, the sensor may be used to identify a particular species associated with the interaction.

Preferably, the sensor or sensor array is used for the identification of a target molecule. For certain types of interaction it is preferred that the target molecule is a bioconjugate of a probe molecule.

According to another aspect of the present invention, there is provided a method for detecting a molecular interaction comprising the steps of:
immobilizing at least one probe molecule on an exposed metal sensor electrode which forms part of an extended gate structure of a field effect transistor (FET), the extended gate structure and a core structure of the FET being located on substantially separate regions of a substrate;
placing an electrolyte containing at least one target molecule in contact with the probe molecule; and,
detecting a change in an electrical characteristic of the FET in response to a molecular interaction between the probe molecule and the target molecule at the exposed surface of the metal sensor electrode.

The method provides a simple way to detect interactions between two types of molecules and generate a characteristic electrical signal which can be monitored and processed as required.

Preferably, the method further comprises the step of applying a voltage difference between a part of the FET structure and a reference electrode which is in contact with the electrolyte. By applying a voltage difference in this way, both the rate of immobilization and the resulting density of probe molecules may be controlled. Furthermore, the molecular interaction rate may also be increased, thereby permitting data collection at near real-time speeds.

Sometimes the density of probe molecules is not sufficient to adequately cover the sensor electrode. It is therefore preferred that the method further comprises the step of positioning spacer molecules between probe molecules on the sensor electrode, the spacer molecules being substantially inert to the target molecules.

The detection method can be improved by suitable labelling of the interaction species, particularly if the change in FET electrical characteristic is enhanced

Preferably, the method further comprises the step of labelling the target molecule with an electrically charged molecule.

Preferably, the method further comprises the step of providing an electrically charged molecule that binds to a product of the molecular interaction between the probe molecule and the target molecule.

As a result of the ability to detect a specific molecular interaction, the method may also be used to identify a specific species associated with the interaction. In particular, it is preferred that the method is used for identifying DNA by detecting the hybridization of DNA.

In summary, the present invention provides a versatile electrical sensor and sensing method that can be used to monitor a wide variety of molecular interactions and thereby also be used in the identification of particular target species. A particularly important application is in the identification of DNA by detecting the hybridization process. The use of a FET device provides internal amplification, whilst the extended gate architecture facilitates electrical and chemical isolation of the core part of the FET structure from the exposed metal sensor region. The design also facilitates the provision of a separate electrical connection to the sensor electrode for the application of a control voltage. An applied voltage allows control of the probe immobilization process for gate functionalization and also control over the subsequent interaction with target molecules contained within an electrolyte. Increased speed can be achieved in this way. The single sensor device is easily extended to an integrable array of sensors, which can provide greater device functionality and monitoring capability. The extended gate architecture of the individual sensor ensures greater isolation between each cell in the array.

### BRIEF DESCRIPTION OF THE DRAWINGS

Examples of the present invention will now be described in detail with reference to the accompanying drawings, in which:

FIG. 1 shows the structure of an EGFET;

FIG. 2 shows a cross-section through an EGFET with functionalized gate and reference electrode;

FIG. 3A shows the current-voltage characteristics of an EGFET before and after probe immobilization on the sensing electrode;

FIG. 3B shows the current-voltage characteristics of an EGFET before and after DNA probe immobilization and also after hybridization with a complementary strand;

FIG. 4 illustrates a linear array of sensing electrodes with capture electronics; and,

FIGS. 5 shows a circuit for providing switchable connection to a sensing electrode, suitable for use with two-dimensional sensor array.

### DETAILED DESCRIPTION

The present invention is directed to the detection of a chemical, biochemical or biological interaction which results in a change of the electric potential distribution at the interface between the functionalized metal gate of a Field Effect Transistor (FET) and an electrolyte. In contrast to the conventional bipolar transistor, the FET transistor consisting of a source, gate, and drain, the action of which depends on the flow of majority carriers past the gate from the source to the drain. The flow is controlled by the transverse electric field under the gate. A metal-insulator-semiconductor type FET (MISFET) is preferred due to superior performance as compared to other types of FET. There are also many varieties of MISFET that are suitable for the purpose of detecting molecular interactions by means of a functionalized gate according to the present invention. One such class is the thin-film transistor (TFT), which itself has many variants, including the single crystal or single grain active layer TFT, the polycrystalline silicon TFT, the amorphous silicon TFT and the organic TFT.

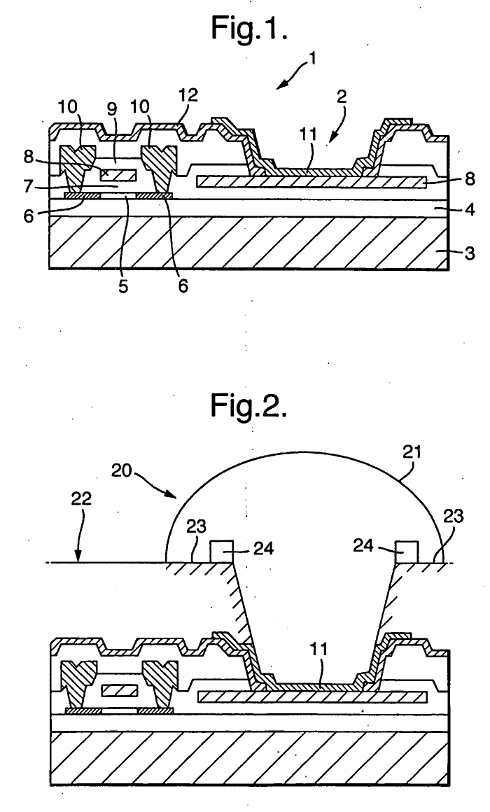

The present invention makes use of a FET having a gate with an extended structure, in contrast to the more usual FET structure. A FET with this type of gate structure is often termed an Extended Gate Field Effect Transistor (EGFET). FIG. 1 shows an example of a polycrystalline silicon type TFT 1 having an extended gate structure 2. The TFT is formed on a substrate 3 and comprises a layer of SiO₂ 4 and a layer of poly-Si 5, in which the source and drain 6 are located. The tantalum (Ta) gate 8 is separated from the poly-Si layer 5 by an SiO₂ layer (the gate dielectric) 7 and is covered by another SiO₂ layer (the field oxide) 9. The source and drain 6 are provided with aluminium (Al) contacts 10. The extended gate structure 2 includes a chromium (Cr) or gold (Au) sensor electrode 11 formed on part of the Ta gate 8. A protective layer of Si₃N₄ 12 covers the majority of the structure, although it is noted that the sensor electrode 11 extends over a portion of the Si₃N₄ layer 12, thereby permitting external electrical connection to the sensor electrode 11.

A typical process for fabricating the polycrystalline silicon EGFET of FIG. 1 would comprise the following steps:
(1) a-Si thin film deposition on Glass substrate;
(2) Laser crystallization to poly-Si thin film;
(3) Poly-Si channel patterning;
(4) Gate oxide deposition;
(5) Gate metal (Tantalum) deposition and patterning;
(6) Ion Doping n+ or p+;
(7) Field oxide deposition;
(8) Contact hole formation above source and drain;
(9) Al deposition to form the source and drain contact;
(10) SiO₂ film deposition;
(11) Si₃N₄ film deposition;
(12) 2^{nd} contact formation above the extended gate to open the Si₃N₄/SiO₂ bi-layer;
(13) Chromium/Gold deposition and patterning;

An EGFET of the type shown FIG. 1 has the advantage of spatially separating the sensing area, namely the metal sensor electrode where voltage modulation occurs, from the field effect transistor (the amplifier). Thus, the core transistor area can be isolated chemically and electrically, for example by using a protective film of polyimide, which avoids contamination, electrical current leakage and stability problems. Furthermore, the EGFET architecture facilitates the construction of more complex sensing areas, such as nanostructured electrodes, membranes, microchambers and the connection to microfluidic devices.

FIG. 2 shows a sensor 20, according to the present invention, which is based on the EGFET of FIG. 1. The sensor includes an electrolyte drop 21, which is confined near the sensor electrode 11 by the combination of a hydrophobic surface 22 and a hydrophilic surface 23, the electrolyte 21 being in contact with both the sensor electrode 11 and a reference electrode 24. Here, only a cross-section through the annular reference electrode is visible. As illustrated, the EGFET architecture permits confinement of the electrolyte to the sensing area of the extended gate structure, thereby completely decoupling, electrically or otherwise, the sensing and amplification regions.

A FET is typically characterized by the variation in drain current (I_{D}) with applied gate-source voltage (V_{GS}). When the gate metal of a MISFET is placed in contact with an electrolyte and a voltage is applied between the source of the FET and a reference electrode, which is also in contact with the electrolyte, a change in the surface dipole magnitude (χ) occurs at the interface between the gate and the electrolyte. This is accompanied by changes in potential differences within the device, including the potential (φ₀) across the electrochemical double layer. As a consequence of these changes, the I_{D}-V_{GS} characteristic of the FET is shifted along the voltage axis. This shift may be calibrated for different types of electrolyte.

In the present invention, one or more types of biological, organic or other types of molecules, here termed probe molecules, are immobilized on the metal gate via some chemical or biochemical process. Particular examples of probe molecules include proteins, antibodies and antigens, vitamins, peptides, sugars and oligonucleotides including DNA, RNA and PNA. The modified metal gate of the FET is then described as a functionalized gate. The presence of immobilized chemical species leads to a further change of χ, brought about by various microscopic phenomena, including the charge distribution of the immobilized chemical species and interactions between the functionalized gate and the electrolyte, such as chemisorption or physisorption of electrolyte molecules. The corresponding effect on the potential φ₀ leads a to change in the I_{D}-V_{GS} characteristic of the FET, which can broadly be described as a shift along the voltage axis, as compared to the FET with an unmodified gate.

Further changes in χ and φ₀ occur when the probe molecules interact with other species present in the electrolyte. In particular, these species will have been intentionally introduced into the electrolyte and are thus termed target molecules. The change may be especially marked if the target molecule is the bioconjugate of the probe molecule. For example, when a gate functionalized with a given strand of DNA probe is exposed to a target with the complementary strand, hybridization occurs. Since the total negative charge carried by the hybridized molecule is twice that of the single stranded oligomer, χ and φ₀ change. By contrast when the functionalized gate is exposed to a non-complementary strand, no binding occurs and the above parameters are unchanged. Thus the shift, or any other change in the I_{D}-V_{GS} characteristic, can be used to detect DNA hybridization. The method may be extended to other chemical and biochemical systems, such as proteins and cells.

In order to amplify, or indeed induce, the change of χ and φ₀ change upon interaction between the probe and target molecules, the target molecules can be biochemically labelled with electrically charged molecules. Alternatively, electrically charged molecules that bind specifically to the bioconjugate probe-target specie can be added to the system to enhance or induce the changes.

If there are areas of the gate metal that are not covered by the probe molecules, and are therefore exposed to the electrolyte, the effectiveness of the method can be reduced. For this reason, molecules that are inert to the target and carry a much lower charge can be used to passivate these areas. Such molecules are usually termed spacer molecules. The effectiveness of the method is also reduced if the distance between probe molecules is larger that the characteristic Debye length in the electrolyte. The density of probe molecules may be controlled by applying a voltage between the gate metal and the reference electrode, whilst the Debye length can be controlled by changing the ionic concentration of the solution.

An example of the procedure for the chemical/biochemical preparation of an EGFET sensor for detecting DNA hybridization according to the present invention is as follows. The electrolyte comprises a 50 mM phosphate buffered saline (PBS) solution containing 50 mM sodium chloride (NaCl), with pH 7.0. Single stranded DNA (ssDNA) consisting of 20 base pairs of Adenine and modified on the 5′ end by: HS—(CH₂)₆—PO₄—(CH₂CH₂O)₆-ssDNA is immobilized on the gold sensor electrode using a concentration of 1 μM in a 1 M potassium phosphate buffer solution (pH 7) containing 1 M NaCl and 1 mM ethylene diamine tetraacetic acid (EDTA). In this implementation no separate connection to the sensing electrode is provided, but the source and drain are connected together and a voltage of +0.3 V is applied between them and a platinum wire immersed in the solution containing the modified DNA. The immobilization is performed over a period of approximately 3 hours, after which the substrate is washed with pure H₂O and 10 mM NaCl containing 10 mM EDTA. In order to create a spacer between the DNA molecules, the chemical mercaptohexanol, HS—(CH₂)₆—OH, is subsequently immobilized over a 1 hour period in a concentration of 1 mM in a 1 M potassium phosphate buffer solution (pH 7) containing 1 M NaCl and 1 mM EDTA. After immobilization of the spacer molecules the substrate is again washed with H₂O and NaCl/EDTA.

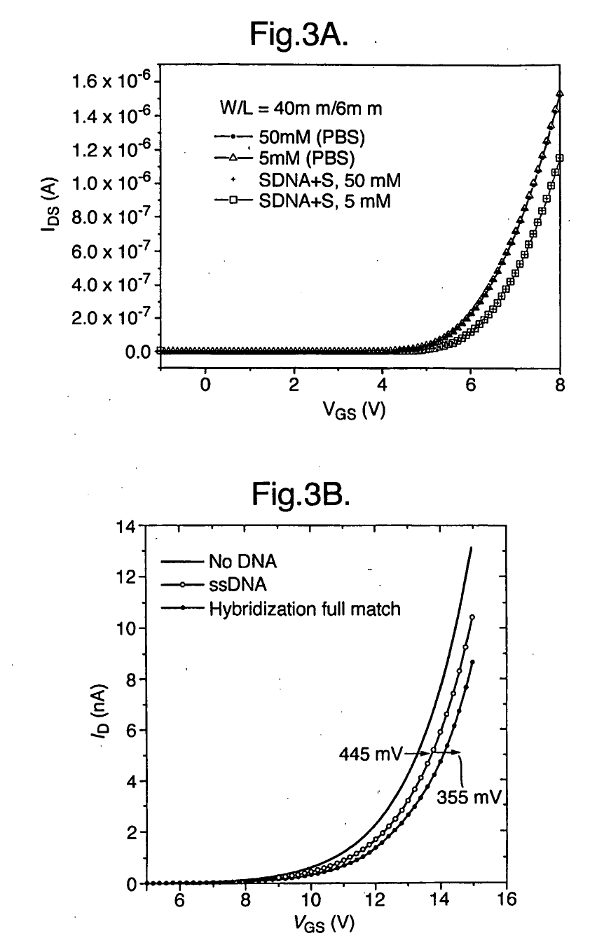

FIG. 3A shows the measured I_{D}-V_{GS} characteristic for an n-channel PTFT EGFET, prepared in the manner described above, both before and after DNA probe immobilization. As can be seen, once a threshold gate-source voltage (V_{GS}) of approximately 5V is exceeded, there is a rapid rise in drain current (I_{D}) with further increase in V_{GS}. Data is shown for two different concentrations of the phosphate buffered saline (PBS) solution, 5 mM and 50 mM, with the two characteristic curves lying on top of one another. Data is also shown for the functionalized gate with two different concentrations of the immobilized DNA probe. Again, both I_{D}-V_{GS} curves lie on top of one another, but the rise characteristic is clearly moved to higher gate-source voltage as compared to the unfunctionalized gate in the presence of the PBS solution.

In the presence of complementary target DNA, the process of hybridization leads to a further shift in the I_{D}-V_{GS} characteristic. To demonstrate this experimentally, single stranded DNA (ssDNA) consisting of 18 base pairs and sequence 5′-ACCATTTCAGCCTGTGCT modified at the 5′ by HS—(CH₂)₆—PO₄—(CH₂CH₂O)₆-ssDNA was immobilized on the gate metal of a 50 μm×6 μm TFT, together with spacer molecules consisting of mercaptohexanol, HS—(CH₂)₆—OH, in a molar ratio of 1:1. A total concentration of 2 μM was used in a 1 M potassium phosphate buffer pH 7.0 containing 1 M NaCl, 5 mM MgCl₂ and 1 mM ethylene diamine tetraacetic acid (EDTA). After immobilization, the substrate was washed with pure H₂O and 10 mM NaCl containing 10 mM EDTA. Complementary DNA strands with sequence 3′-TGGTAAAGTCGGACACGA were used in a concentration of 1 μM in 1 M phosphate buffer pH 7.0 with 1 M NaCl. After interaction, the substrate was again washed with H₂O.

The I_{D}-V_{GS} characteristics of the TFT were measured using a parameter analyser and the voltage was applied to the gate through an Ag/AgCl reference electrode, immersed in the measuring buffer and referenced to the TFT. During the measurements, V_{GS} was swept from negative voltage to positive voltage and back and V_{DS} was kept constant at 0.1V. During the immobilization and hybridization processes, both drain and source were kept electrically grounded. FIG. 3B shows the I-V characteristics of the TFT before immobilization, after 18-mer ssDNA immobilization and after hybridization with the complementary strand. After overnight ssDNA immobilization the I-V curves show a shift of 445 mV. After hybridization with the complementary strand a further shift of 355 mV is observed. Hybridization occurred for 1 hour with a voltage of 0.3 V applied to the source and drain of the transistor with respect to the DNA solution. The results clearly demonstrate a change in TFT characteristics attributable to the detection of the DNA hybridization process.

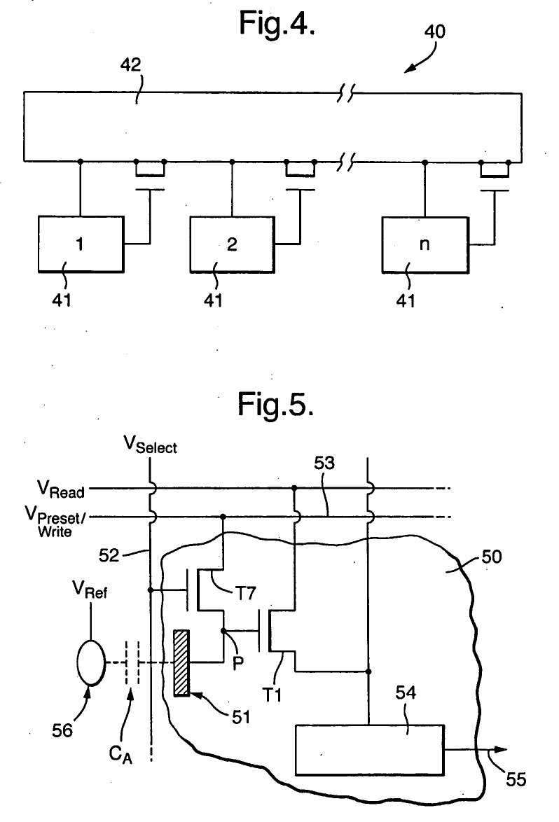

Although the examples given so far only deal with single sensor devices, it is quite possible to extend the detector to an array of sensors. FIG. 4 illustrates an embodiment 40 of this concept in terms of a one-dimensional linear array (1,2 . . . n) of functionalized-gate EGFET sensors 41. Also shown is the provision of scan and sensing circuitry 42 connected to each gold sensing electrode in the array. The scan and sensing circuitry can be located on an external microchip or could be monolithically integrated with the sensor array. The use of an array provides further functionality to the overall sensor, including spatial resolution of a molecular interaction across the array, and also temporal resolution if each sensor is differently time-gated. A further advantage of the EGFET design becomes apparent when used in an array, namely the ease of isolation between individual sensors, leading to reduced interference between adjacent cells is. This is difficult to achieve using prior art device architectures.

The sensor array concept described above can, of course, be extended to a two-dimensional array of sensors. In this case it is desirable that provision is made for a separate switchable electrical connection to each sensing electrode in the array. FIG. 5 shows a suitable circuit design 50 for switchable connection to a sensor transistor. Each sensor cell consists of a sensing transistor T1, whose gate is connected to a switching transistor T7. The metal electrode 51 of the gate is capacitively coupled to a reference electrode 56 at potential V_{REF}. The operation of the circuit can be illustrated by way of an example, as follows, assuming a device with n-channel FETs. In order to select Au electrode 51 for immobilization of the specific probe present in the solution, V_{SELECT} goes HIGH for column 52 and V_{PRESET/WRITE}−V_{REF} goes positive for row 53. V_{SELECT} is LOW for all remaining columns and V_{PRESET/WRITE}−V_{REF} is zero or negative for all remaining rows. In this way the positive voltage necessary to promote the DNA probe immobilization is selectively applied. In the hybridization stage, it is not necessary to apply the promoting voltage selectively and, therefore, a plurality of electrodes can be simultaneously selected.

Transistor T7 can also be used to select the sensor location in the ‘interrogation’ or readout stage. In this case V_{PRESET/WRITE}=V_{REF}=V_{ON} and V_{READ} is LOW for all rows. Initially V_{SELECT} is HIGH for all columns. In this condition no current is detected by the readout electronics 54. Now V_{READ} goes HIGH for row 53 and the current measured by each readout circuit corresponds to V_{GS}=V_{ON} for each transistor of row 53. Then V_{SELECT} goes LOW for all columns and the current measured corresponds to the gate voltage modulated by the surface dipole effect. It is crucial in the case of a large high-resolution array to minimize cross talk and interference. Hence, again, the use of an EGFET design for the sensing transistor and the confinement of the electrolyte to the sensing area provide a great advantage over the prior art sensor designs.

1. A sensor for use in the detection of a molecular interaction comprising a field effect transistor (FET) having an extended gate structure and a core structure including a drain and a source, the core structure and the extended gate structure being located on substantially separate regions of a substrate, the extended gate structure including an exposed metal sensor electrode on which probe molecules can be immobilized, wherein the sensor is operative to produce a change in a drain current (I_{D}) versus gate-source voltage (V_{GS}) electrical characteristic of the FET in response to molecular interaction at the exposed surface of the metal sensor electrode.

2. A sensor according to claim 1, wherein the FET comprises a metal insulator semiconductor (MIS) type structure.

3. A sensor according to claim 1, further comprising a passivation layer located above the FET core structure.

4. A sensor according to claim 3, wherein the passivation layer is formed from at least one material selected from a group which includes polyimide, BCB, SiO₂ and Si₃N₄.

5. A sensor according to claim 1, further comprising means for electrical connection to the sensor electrode.

6. A sensor according to claim 1, wherein the metal sensor electrode is substantially formed from gold.

7. A sensor according to claim 1, wherein the metal sensor electrode is substantially formed from chromium.

8. A sensor according to claim 1, wherein the metal sensor electrode is substantially formed from platinum.

9. A sensor according to claim 1, further comprising a reference electrode.

10. A sensor according to claim 9, further comprising means for applying a voltage difference between a part of the FET and the reference electrode.

11. A sensor according to claim 1, further comprising at least one probe molecule immobilized on the exposed metal sensor electrode.

12. A sensor according to claim 11, wherein the probe molecule is selected from a group which includes proteins, antibodies and antigens, vitamins, peptides, sugars and oligonucleotides, including DNA, RNA and PNA.

13. A sensor according to claim 11, further comprising an electrolyte in contact with the at least one probe molecule.

14. A sensor array comprising a plurality of sensors, wherein each sensor is in accordance with claim 11.

15. A sensor array according to claim 14, further comprising scan and sensor circuitry connected to the sensor electrodes of at least two sensors in the array.

16. A sensor array according to claim 14, further comprising means for a switchable connection to the sensor electrode of at least one sensor in the array.

17. The use of a sensor according to claim 13 for the identification of a target molecule.

18. The use of a sensor array according to claim 14 for the identification of a target molecule.

19. A use of a sensor or sensor array according to claim 18, wherein the target molecule is a bioconjugate of a probe molecule.

20. A method for detecting a molecular interaction comprising the steps of:
immobilizing at least one probe molecule on a sensor electrode which forms part of an extended gate structure of a field effect transistor (FET), the extended gate structure and a core structure of the FET being located on substantially separate regions of a substrate, the core structure including a drain and a source;
placing an electrolyte containing at least one target molecule in contact with the at least one probe molecule; and, detecting a change in a drain current (I_{D}) versus gate-source voltage (V_{GS}) electrical characteristic of the FET in response to a molecular interaction between the at least one probe molecule and target molecule at the exposed surface of the metal sensor electrode.

21. A method according to claim 20, further comprising the step of applying a voltage difference between a part of the FET and a reference electrode which is in contact with the electrolyte.

22. A method according to claim 20, further comprising the step of positioning spacer molecules between probe molecules on the sensor electrode, the spacer molecules being substantially inert to the target molecules.

23. A method according to claim 20, further comprising the step of labelling the target molecule with an electrically charged molecule.

24. A method according to claim 20, further comprising the step of providing an electrically charged molecule that binds to a product of the molecular interaction between the probe molecule and the target molecule.

25. A method for identifying DNA comprising the step of detecting the hybridization of DNA using the method of claim 19.
